(19) United States
(12) Patent Application Publication
(10) Pub. No.: US 2022/0269320 A1
(43) Pub. Date: Aug. 25, 2022

(54) EXPANDABLE HOST, EXPANSION MODULE AND COMPUTATION DEVICE

(71) Applicant: CINCOZE CO., LTD., New Taipei City (TW)

(72) Inventor: HSIN-TE CHIEN, New Taipei City (TW)

(21) Appl. No.: 17/320,232

(22) Filed: May 14, 2021

(30) Foreign Application Priority Data
Feb. 22, 2021 (TW) 110106117

(51) Int. Cl. G06F 1/18; H05K 5/00

(52) U.S. Cl. CPC G06F 1/182; H05K 5/0073

(57) ABSTRACT

A computation device includes an expandable host and an expansion module. The expandable host includes a host casing, a host circuit board, a computation unit and an electrical unit. The host casing has an opening. The host circuit board is disposed in the host casing and has a slot. The slot is disposed at the opening. The computation unit is disposed on the host circuit board. The electrical unit is disposed in the host casing and electrically connected to the host circuit board. The expansion module includes an expansion casing, an expansion circuit board and an expansion unit. The expansion circuit board is penetratingly disposed at the expansion casing and includes an insertion portion protruding from the expansion casing. The expansion unit is disposed in the expansion casing and electrically connected to expansion circuit board. The expansion unit includes a processor.

### CROSS-REFERENCE TO RELATED APPLICATION

This non-provisional application claims priority under 35 U.S.C. § 119(a) on Patent Application No(s). 110106117 filed in Taiwan, R.O.C. on Feb. 22, 2021, the entire contents of which are hereby incorporated by reference.

### BACKGROUND OF THE INVENTION

### 1. Field of the Invention

The present disclosure relates to an expandable host, expansion module and computation device, and in particular to an expandable host and an expansion module which can be freely coupled together and separated and a computation device comprising the expandable host and expansion module.

### 2. Description of the Related Art

Computers are electronic products widely used in daily life and industrial sector. In general, a computer comprises a casing, a computation unit for computing and processing a command, an expansion unit for providing specific functions, and an electrical unit for supplying power to the aforesaid units. The computation unit, expansion unit and electrical unit are disposed in the same casing. However, in case of a change in users' demand for computation functionality or hardware specifications, the casing can no longer house the changed units to the detriment of usage flexibility. In addition, to carry out inspection or maintenance on a computer being manufactured by a production line, the computer must be removed from the production line, thereby causing the production line to be put aside and incurring economic loss.

### BRIEF SUMMARY OF THE INVENTION

An objective of the present disclosure is to provide an expandable host, expansion module and computation device which can be freely coupled together and separated to enhance usage flexibility and operation efficiency of a production line.

To achieve at least the above objective, the present disclosure provides an expandable host comprising a host casing, a host circuit board, a computation unit and an electrical unit. The host casing has an opening. The host circuit board is disposed in the host casing and has a slot. The slot is aligned with the opening. The computation unit is disposed on the host circuit board. The electrical unit is disposed in the host casing and electrically connected to host circuit board.

In an embodiment, the expandable host further comprises a guide portion, wherein the guide portion is disposed in the host casing, connected to the opening and extended toward the slot.

In an embodiment, the slot comprises a first bus and a second bus. One of first bus and second bus is electrically connected to computation unit. The other is electrically connected to electrical unit. The second bus is of a greater width than the first bus.

In an embodiment, the computation unit is a CPU.

The present disclosure further provides an expansion module. The expansion module comprises an expansion casing, an expansion circuit board and an expansion unit. The expansion circuit board is penetratingly disposed at the expansion casing and comprises an insertion portion, wherein the insertion portion protrudes from the expansion casing. The expansion unit is disposed in the expansion casing and electrically connected to expansion circuit board, wherein the expansion unit comprises a processor.

In an embodiment, the insertion portion comprises a first terminal and a second terminal. One of the first terminal and second terminal transmits data signals. The other transmits power. The second terminal is of a greater width than the first terminal.

In an embodiment, the expansion module further comprises an expansion computation unit, wherein the expansion computation unit is disposed in the expansion casing and electrically connected to expansion circuit board.

In an embodiment, the expansion module further comprises an expansion unit support, wherein the expansion unit support is disposed in the expansion casing and fixedly disposed at or slidably disposed at expansion circuit board. The expansion unit is mounted on expansion unit support.

In an embodiment, the expansion unit is a display card.

The present disclosure further provides a computation device which comprises the expandable host and expansion module, wherein the insertion portion is selectively inserted into the slot via the opening.

In an embodiment, the computation device further comprises a mounting support, wherein the mounting support is fixedly disposed at the expandable host and expansion module and comprises a fixing portion. The fixing portion protrudes relative to the host casing and expansion casing.

Therefore, the expandable host and expansion module are coupled together and separated freely by means of the insertion portion, opening and slot. To switch to a new expansion unit of different specifications, users can change the expansion module, thereby enhancing ease of use. The computation device comprises the expandable host and expansion module. To perform inspection or maintenance on constituent components of the expansion module, the expansion module is removed from the expandable host to maintain the operation of the expandable host, so as to allow the production line to operate continuously and avoid economic loss.

### BRIEF DESCRIPTION OF THE DRAWINGS

FIG. 1 is a perspective view of a computation device according to an embodiment of the present disclosure.

FIG. 2 is a front view of an expandable host of FIG. 1.

FIG. 3 is a cross-sectional view taken along line X-X of FIG. 2.

FIG. 4 is an enlarged view of area A of FIG. 3.

FIG. 5 is a lateral view of an expansion module of FIG. 1.

FIG. 6 is a cross-sectional view taken along line Y-Y of FIG. 5.

FIG. 7 is a schematic view of constituent elements of the computation device of FIG. 1.

### DETAILED DESCRIPTION OF THE INVENTION

To facilitate understanding of the object, characteristics and effects of this present disclosure, embodiments together with the attached drawings for the detailed description of the present disclosure are provided.

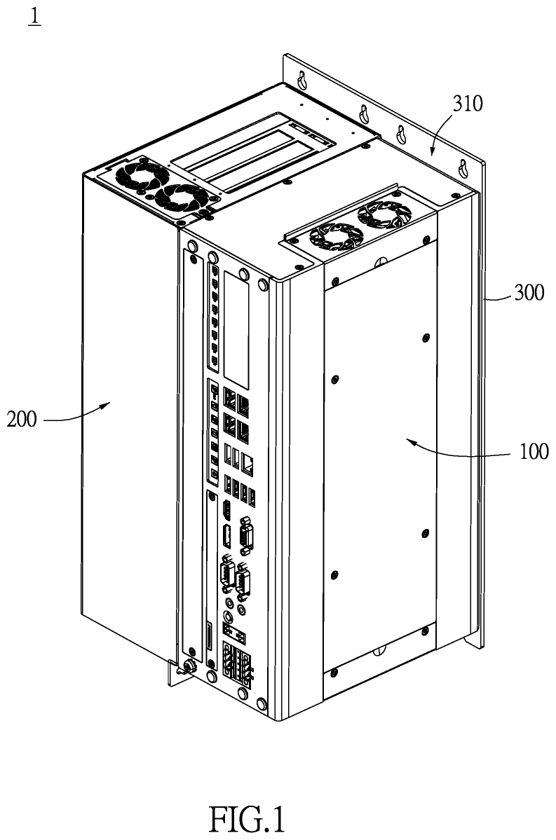

Referring to FIG. 1, there is shown a perspective view of a computation device according to an embodiment of the present disclosure. In this embodiment, the computation device 1 is, for example, a personal computer or an industrial computer and comprises an expandable host 100 and an expansion module 200. The expandable host 100 and expansion module 200 can be freely connected and separated. Preferably, the computation device 1 further comprises a mounting support 300. The mounting support 300 is, for example, adapted to mount the expandable host 100 and expansion module 200 at a specific position on a wall or a metal board. The mounting support 300 is fixedly disposed at the expandable host 100 and expansion module 200 and comprises a fixing portion 310. The fixing portion 310 protrudes relative to the casings of the expandable host 100 and expansion module 200 and forms a plurality of fastening-oriented holes. Users fix the expandable host 100 and expansion module 200 to the mounting support 300 and then allow the expandable host 100 and expansion module 200 to be penetratingly disposed at the holes on the fixing portion 310 with fastening elements, such as screws or rivets; hence, the computation device 1 is fastened to the specific position, thereby enhancing ease of use.

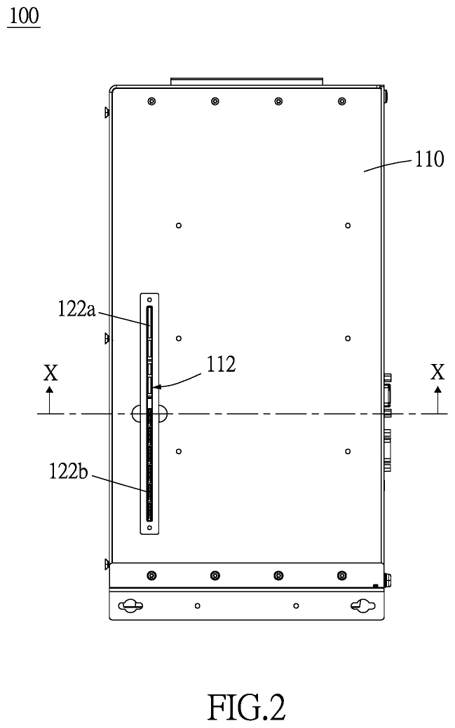

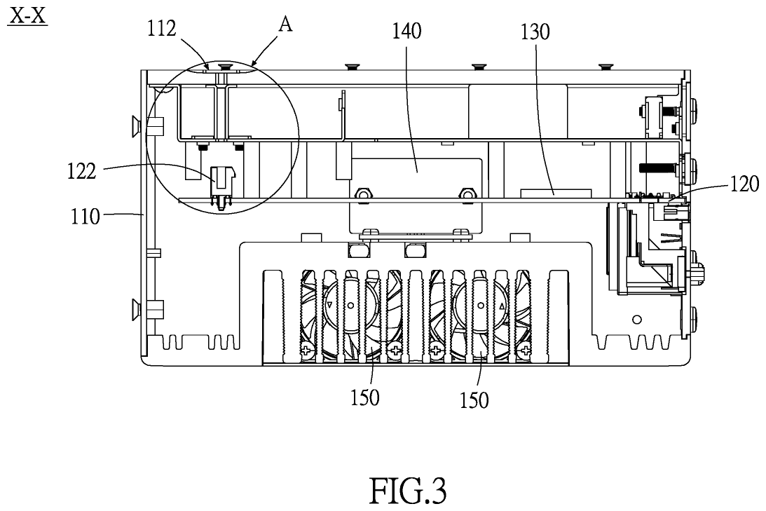

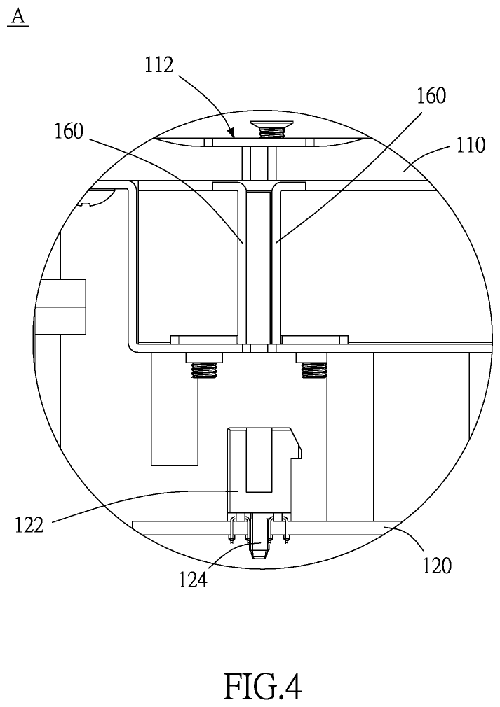

Refer to FIG. 2 through FIG. 4. FIG. 2 is a front view of an expandable host of FIG. 1. FIG. 3 is a cross-sectional view taken along line X-X of FIG. 2. FIG. 4 is an enlarged view of area A of FIG. 3. As shown in the diagrams, in this embodiment, the expandable host 100 comprises a host casing 110, a host circuit board 120, a computation unit 130 and an electrical unit 140, wherein the host circuit board 120 is disposed in the host casing 110; computation unit 130 is, for example, a central processing unit (CPU) and disposed on the host circuit board 120; electrical unit 140 is, for example, a power supplying unit (PSU) disposed in host casing 110 and electrically connected to host circuit board 120 to rectify and transform an external power into current and voltage suitable for being inputted to the electronic components of the expandable host 100. Preferably, the expandable host 100 further comprises a heat dissipation unit 150, wherein the heat dissipation unit 150 is, for example, a module (comprising fans and fins) disposed in host casing 110 and electrically connected to electrical unit 140, such that heat generated as a result of the operation of constituent components of the expandable host 100 is released to the outside of the host casing 110.

The expandable host 100 either works independently or integrates with the expansion module 200 to attain robust work performance or computation capability. Referring to FIG. 2 and FIG. 3, the host casing 110 has an opening 112, and a slot 122 is formed on host circuit board 120. The slot 122 receives an electronic component and is aligned with the opening 112. Thus, to put the computation device 1 into use, the expansion module 200 is inserted into the slot 122 of the expandable host 100 via the opening 112, such that the expandable host 100 and expansion module 200 are coupled together to enhance work performance or computation capability. To reduce power output or perform maintenance or inspection of the expansion module 200, users remove the expansion module 200 from the expandable host 100, such that the expandable host 100 operates independently and thus prevents the production line from being put aside or grinding to a halt, minimizes financial loss, and simplifies a maintenance or inspection process.

Preferably, at least one fastening hole is formed on the host casing 110 and positioned proximate to the rim of the opening 112. There is a height difference between the opening 112 and the host casing 110. To remove the expansion module 200 from the expandable host 100, users fasten a cover board corresponding in size and shape to the opening 112 to the opening 112 with some fastening elements, such as screws or rivets, such that not only is ambient dust unlikely to intrude into the host casing 110 to otherwise contaminate or damage internal components, but the host casing 110 also has a neat appearance.

Referring to FIG. 2, the slot 122 comprises a first bus 122a and a second bus 122b. The first bus 122a and first bus 122b are of equal width or different widths. This embodiment is exemplified by the second bus 122b being of greater width than the first bus 122a. With the expansion module 200 being inserted into the slot 122, its electronic components need high-power power supply. To this end, the expandable host 100 transmits data signals and power to electronic components of expansion module 200 via first bus 122a and second bus 122b, respectively. Thus, one of first bus 122a and second bus 122b is electrically connected to computation unit 130, whereas the other is electrically connected to electrical unit 140. In this embodiment, first bus 122a is electrically connected to computation unit 130, and second bus 122b is electrically connected to electrical unit 140. Thus, when expansion module 200 is inserted into slot 122, first bus 122a receives data signals from computation unit 130 and sends the data signals, whereas second bus 122b receives power supply from electrical unit 140. Therefore, two different types of electrical signals do not interfere with each other, and their transmission efficiency increases.

Referring to FIG. 4, slot 122 is fastened to host circuit board 120 with a fastening element 124. The fastening element 124 is, for example, a rivet. To provide direction guide and touch feedback required for users to insert the component into slot 122, expandable host 100 further comprises a guide portion 160. The guide portion 160 is, for example, a guide rail made of a resilient metal plate disposed in host casing 110, connected to opening 112 and extended toward slot 122. When users insert the electronic components of expansion module 200 into opening 112, the lower ends of the electronic components are blocked by the guide portion 160 and thus firmed inserted into slot 122 along the extension direction.

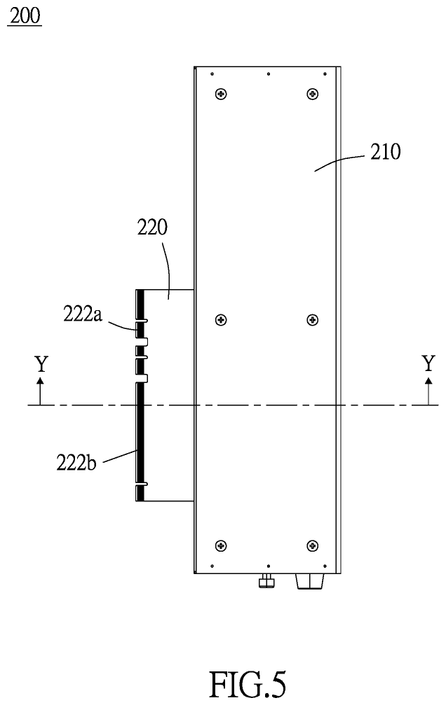

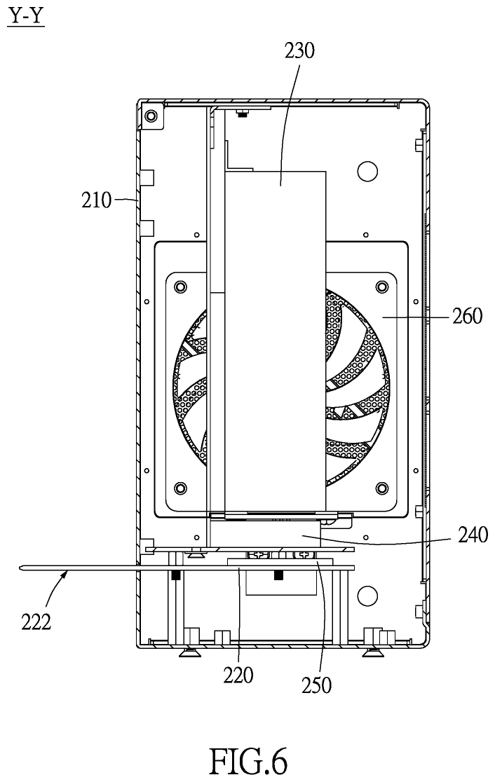

Refer to FIG. 5 and FIG. 6. FIG. 5 is a lateral view of an expansion module of FIG. 1. FIG. 6 is a cross-sectional view taken along line Y-Y of FIG. 5. As shown in the diagrams, in this embodiment, the expansion module 200 comprises an expansion casing 210, an expansion circuit board 220 and an expansion unit 230, wherein the expansion circuit board 220 is penetratingly disposed at the expansion casing 210; expansion unit 230 is, for example, a display card and comprises a graphic processing unit (GPU) disposed in expansion casing 210 and electrically connected to expansion circuit board 220. Preferably, expansion module 200 further comprises an expansion unit support 240, wherein the expansion unit support 240 is disposed in the expansion casing 210 and fixedly disposed at or slidably disposed at expansion circuit board 220 to adjust the position of expansion unit 230 relative to expansion circuit board 220. The expansion unit 230 is mounted on expansion unit support 240.

The expansion module 200 is inserted into slot 122 of expandable host 100, and thus expandable host 100 has robust performance. Referring to FIG. 5 and FIG. 6, expansion circuit board 220 comprises an insertion portion 222, wherein the insertion portion 222 protrudes from the expansion casing 210 and comprises a first terminal 222a and a second terminal 222b. The first terminal 222a and second terminal 222b correspond in function and size to first bus 122a and second bus 122b, respectively. Thus, in this embodiment, data signals inputted and outputted by expansion unit 230 are transmitted by the first terminal 222a, whereas second terminal 222b transmits power to expansion unit 230. The second terminal 222b is of a greater width than first terminal 222a. When users insert insertion portion 222 into slot 122 via opening 112, expansion unit 230 receives high-power power supply (500 W in this embodiment) from electrical unit 140 via second bus 122b and second terminal 222b and receives data signals from computation unit 130 via first bus 122a and first terminal 222a. The data signals are sent back to computation unit 130 after being computed by electronic components, such as a processor and memory inside expansion unit 230. Therefore, expandable host 100 has robust and diverse performance.

The expansion module 200 enhances the computing and processing capability of expandable host 100. In this embodiment, the expansion module 200 further comprises an expansion computation unit 250 and an expansion heat dissipation unit 260. The expansion computation unit 250 is, for example, a central processing unit and is disposed in the expansion casing 210. The expansion heat dissipation unit 260 is, for example, a fan set. The expansion computation unit 250 and expansion heat dissipation unit 260 are electrically connected to expansion circuit board 220. When users insert insertion portion 222 into slot 122, both expansion computation unit 250 and expansion heat dissipation unit 260 receive data signals and power from expandable host 100, assisting expandable host 100 in computation and assisting expansion module 200 in heat dissipation. In a variant embodiment, expansion computation unit 250 is replaced with a storage medium, such as flash memory and hard disk drive, and the present disclosure is not limited thereto.

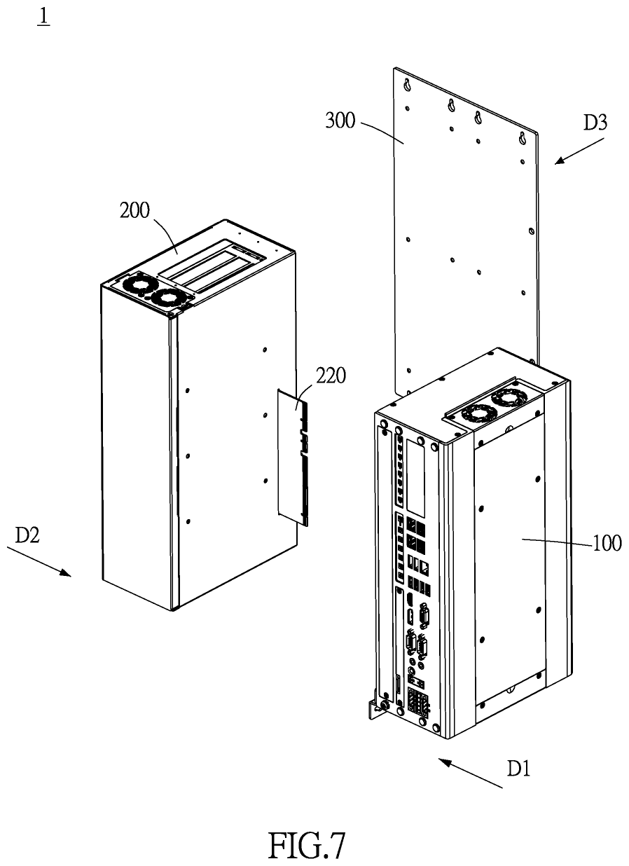

Use of the computation device 1 in this embodiment is described below. Referring to FIG. 7, there is shown a schematic view of constituent elements of the computation device of FIG. 1. As shown in the diagrams, to enhance the display performance or computation performance of expandable host 100, expandable host 100 and expansion module 200 approach each other in first direction D1 and second direction D2 of FIG. 7, respectively, and insertion portion 222 of expansion circuit board 220 is inserted into slot 122 via opening 112. After expandable host 100 and expansion module 200 have been completely and firmly coupled together, the mounting support 300 is moved in third direction D3 and thus fixedly disposed at the expandable host 100 and expansion module 200 with fastening elements, such as screws or rivets. Thus, computation unit 130, electrical unit 140 and expansion unit 230 are disposed in the two independent casings. When expandable host 100 needs expansion module 200 of a different specification, or when internal components of expansion module 200 require inspection or maintenance, only expansion module 200 needs to be removed from expandable host 100 to keep the production line operating continuously and render computation device 1 flexible in terms of application.

While the present disclosure has been described by means of specific embodiments, numerous modifications and variations could be made thereto by those skilled in the art without departing from the scope and spirit of the present disclosure set forth in the claims.

What is claimed is:

1. An expandable host, comprising:
a host casing having an opening;
a host circuit board disposed in the host casing and having a slot disposed at the opening;
a computation unit disposed on the host circuit board; and
an electrical unit disposed in the host casing and electrically connected to the host circuit board.

2. The expandable host of claim 1, further comprising a guide portion disposed in the host casing, connected to the opening and extending toward the slot.

3. The expandable host of claim 1, wherein the slot comprises a first bus and a second bus, wherein one of the first bus and the second bus is electrically connected to the computation unit, and the other is electrically connected to the electrical unit, wherein the second bus is of a greater width than the first bus.

4. The expandable host of claim 1, wherein the computation unit is a central processing unit (CPU).

5. An expansion module, comprising:
an expansion casing;
an expansion circuit board penetratingly disposed at the expansion casing and comprising an insertion portion, the insertion portion protruding from the expansion casing; and
an expansion unit disposed in the expansion casing, electrically connected to the expansion circuit board and comprising a processor.

6. The expansion module of claim 5, wherein the insertion portion comprises a first terminal and a second terminal, wherein one of the first terminal and the second terminal transmits data signals, and the other transmits electricity, wherein the second terminal is of a greater width than the first terminal.

7. The expansion module of claim 5, further comprising an expansion computation unit disposed in the expansion casing and electrically connected to the expansion circuit board.

8. The expansion module of claim 5, further comprising an expansion unit support disposed in the expansion casing and fixedly or slidably disposed at the expansion circuit board, wherein the expansion unit is mounted on the expansion unit support.

9. The expansion module of claim 5, wherein the expansion unit is a display card.

10. A computation device, comprising:
an expandable host, comprising:
a host casing having an opening;
a host circuit board disposed in the host casing and having a slot disposed at the opening;
a computation unit disposed on the host circuit board; and
an electrical unit disposed in the host casing and electrically connected to the host circuit board; and
an expansion module, comprising:
an expansion casing;
an expansion circuit board penetratingly disposed at the expansion casing and comprising an insertion portion, the insertion portion protruding from the expansion casing; and
an expansion unit disposed in the expansion casing, electrically connected to the expansion circuit board and comprising a processor;
wherein the insertion portion is selectively inserted into the slot through the opening.

11. The computation device of claim 10, further comprising a mounting support fixedly disposed at the expandable host and the expansion module and comprising a fixing portion protruding relative to the host casing and the expansion casing.
